(19) United States
(12) Patent Application Publication
(10) Pub. No.: US 2008/0031052 A1
(43) Pub. Date: Feb. 7, 2008

(54) A DOUBLE-BIAS ERASE METHOD FOR MEMORY DEVICES

(75) Inventor: Chao-I Wu, Tainan (TW)

Correspondence Address: BAKER & MCKENZIE LLP;PATENT DEPARTMENT, 2001 ROSS AVENUE, SUITE 2300, DALLAS, TX, 75201, US

(73) Assignee: MACRONIX INTERNATIONAL CO., LTD., Hsinchu (TW)

(21) Appl. No.: 11/461,492

(22) Filed: Aug. 1, 2006

(51) Int. Cl. G11C 16/04; G11C 11/34

(52) U.S. Cl. 365/185.29; 365/185.17

(57) ABSTRACT

A dual-bias erase process for a non-volatile memory device is described. The dual-bias erase process applies a positive bias to the source and drain regions of the memory device, while simultaneously applying a negative bias to the gate region of the memory device. Since a negative bias is applied to the gate, and since no bias is applied from the source to the drain, the memory device is not “turned on” and no electric current will flow through the channel under the gate. The positive biases on the source and drain regions, however, generate minority carriers that are attracted to the gate region by its negative bias. These minority carriers are injected into the nitride by the negative gate bias, thereby erasing any previous programming of the memory device.

### BACKGROUND

1. Field of the Application

The field of this application relates to non-volatile memory devices, and more particularly, to a novel technique for erasing such devices using the application of a double-bias.

2. Background

Memory devices for non-volatile storage of information are in wide use. Examples of such memory devices include read only memory (ROM), programmable ROM (PROM), erasable programmable ROM (EPROM), electrically erasable programmable ROM (EEPROM), and flash EEPROM. A flash memory generally refers to a flash EEPROM, which may be erased in blocks of data instead of one byte at a time. Flash memory is popular in devices that require storage of large amounts of data, such as digital cameras and MP3 players. A popular form of flash memory is based upon “floating gate” memory devices.

One form of flash memory device called SONOS (Silicon Oxide Nitride Oxide Silicon) has been developed for simpler memory fabrication processes. The structure, formation, and operation of SONOS memory devices is described in more detail in the article Boaz Eitan, et al., NROM: A Novel Localized Trapping, 2 Bit Nonvolatile Memory Cell, IEEE Electron Device Letters, vol. 21, no. 11, pp. 543-45, November 2000, which is hereby incorporated by reference into the specification of this application. As mentioned in the Eitan article, the SONOS device is based upon a silicon-oxide-nitride-oxide-silicon (SONOS) charge trapping region rather than a floating gate arrangement. This greatly improves the manufacturability of the memory devices and its scalability for smaller device sizes.

### SUMMARY

The erase time of a SONOS memory device can be improved by applying a dual-bias erase process. The dual-bias erase process applies a positive bias to the source and drain regions of a non-volatile memory device, e.g., a SONOS memory device, while simultaneously applying a negative bias to the gate region of the memory device. During this process, the memory device is not “turned on” and no electric current will flow through the channel under the gate. The positive biases on the source and drain regions, however, induce “leakage current” across this junction.

The dual-bias erase process described herein can erase a non-volatile memory device. In addition, the dual-bias erase process can be used with a dual-bit memory device. According to one aspect, the dual-bias erase process can be applied to the dual-bit non-volatile memory device after only one side of the memory device has been programmed, thus eliminating the necessity for a pre-program step prior to the erase process. Eliminating the pre-program step reduces the time required to program the device and greatly simplifies the erase process. These and other features, aspects, and embodiments of the invention are described below in the section entitled “Detailed Description.”

### BRIEF DESCRIPTION OF THE DRAWINGS

Features, aspects, and embodiments of the inventions are described in conjunction with the attached drawings, in which:

FIG. 1 is a schematic diagram illustrating a cross-sectional view of a conventional non-volatile memory device;

FIG. 2 is a schematic diagram illustrating a cross-sectional view of a conventional non-volatile memory device receiving first program pulse that programs a drain-side of the device;

FIGS. 2A-2C are timing diagrams depicting the timing of the biases applied to the gate, drain, and source of the non-volatile memory device during a first program pulse;

FIG. 3 is a schematic diagram illustrating a cross-sectional view of a conventional non-volatile memory device receiving a second program pulse that programs a source-side of the memory device;

FIGS. 3A-3C are timing diagrams depicting the timing of the biases applied to the gate, drain, and source of the non-volatile memory device during a second program pulse;

FIG. 4 is a schematic diagram illustrating a cross-sectional view of a conventional non-volatile memory device receiving an erase pulse according to one embodiment of the invention;

FIGS. 4A-4C are timing diagrams depicting the timing of the biases applied to the gate, drain, and source of the non-volatile memory device during an erase pulse according to one embodiment of the invention;

FIG. 5 is a schematic diagram illustrating a cross-sectional view of a conventional non-volatile memory device receiving a Fowler-Nordheim program pulse;

FIGS. 5A-5C are timing diagrams depicting the timing of the biases applied to the gate, drain, and source of the non-volatile memory device during the Fowler-Nordheim program pulse;

FIG. 6 is a schematic diagram illustrating a cross-sectional view of a conventional non-volatile memory device receiving an erase pulse according to one embodiment of the invention;

FIGS. 6A-6C are timing diagrams depicting the timing of the biases applied to the gate, drain, and source of the non-volatile memory device during the erase pulse according to one embodiment of the invention;

FIG. 7 is a schematic diagram illustrating a cross-sectional view of a conventional non-volatile memory device receiving an alternative Fowler-Nordheim program pulse;

FIGS. 7A-7C are timing diagrams depicting the timing of the biases applied to the gate, drain, and source of the non-volatile memory device during the alternative Fowler-Nordheim program pulse;

FIG. 8 is a schematic diagram illustrating a cross-sectional view of a conventional non-volatile memory device receiving an erase pulse according to one embodiment of the invention;

FIGS. 8A-8C are timing diagrams depicting the timing of the biases applied to the gate, drain, and source of the non-volatile memory device during the erase pulse according to one embodiment of the invention;

FIG. 9 is a schematic diagram illustrating a cross-sectional view of a conventional non-volatile memory device receiving yet another alternative Fowler-Nordheim program pulse;

FIGS. 9A-9C are timing diagrams depicting the timing of the biases applied to the gate, drain, and source of the non-volatile memory device during the alternative Fowler-Nordheim program pulse;

FIG. 10 is a schematic diagram illustrating a cross-sectional view of a conventional non-volatile memory device receiving an erase pulse according to one embodiment of the invention;

FIGS. 10A-10C are timing diagrams depicting the timing of the biases applied to the gate, drain, and source of the non-volatile memory device during the erase pulse according to one embodiment of the invention;

FIG. 11 is a schematic diagram illustrating a cross-sectional view of a conventional non-volatile memory device receiving yet another alternative Fowler-Nordheim program pulse;

FIGS. 11A-11C are timing diagrams depicting the timing of the biases applied to the gate, drain, and source of the non-volatile memory device during the alternative Fowler-Nordheim program pulse;

FIG. 12 is a schematic diagram illustrating a cross-sectional view of a conventional non-volatile memory device receiving an erase pulse according to one embodiment of the invention;

FIGS. 12A-12C are timing diagrams depicting the timing of the biases applied to the gate, drain, and source of the non-volatile memory device during the erase pulse according to one embodiment of the invention;

FIG. 13 is a diagram depicting the effects of program and erase pulses on a two-bit non-volatile memory device according to one embodiment of the invention; and

FIG. 14 is a diagram depicting the effects of program and erase pulses on a two-bit non-volatile memory device according to another embodiment of the invention.

### DETAILED DESCRIPTION

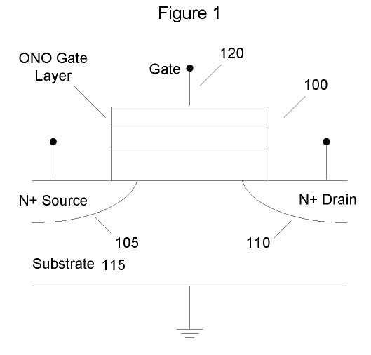

A representative memory device 100 is depicted in FIG. 1. In the example of FIG. 1, memory device 100 is SONOS memory device. It will be understood, however, that the methods described herein can apply to other non-volatile memory devices. The memory device 100 comprises a buried source 105 and a buried drain 110 formed in a substrate 115. Also shown in FIG. 1 is a gate region 120 comprised of an oxide-nitride-oxide (ONO) structure 121. The gate region 120 is formed on atop the substrate 115 and overlaps the source and drain regions (105, 110). In operation, the nitride layer 122 in the gate 120 acts as a charge-trapping region that can store holes and electrons so as to indicate either a programmed or un-programmed state of the memory device 100.

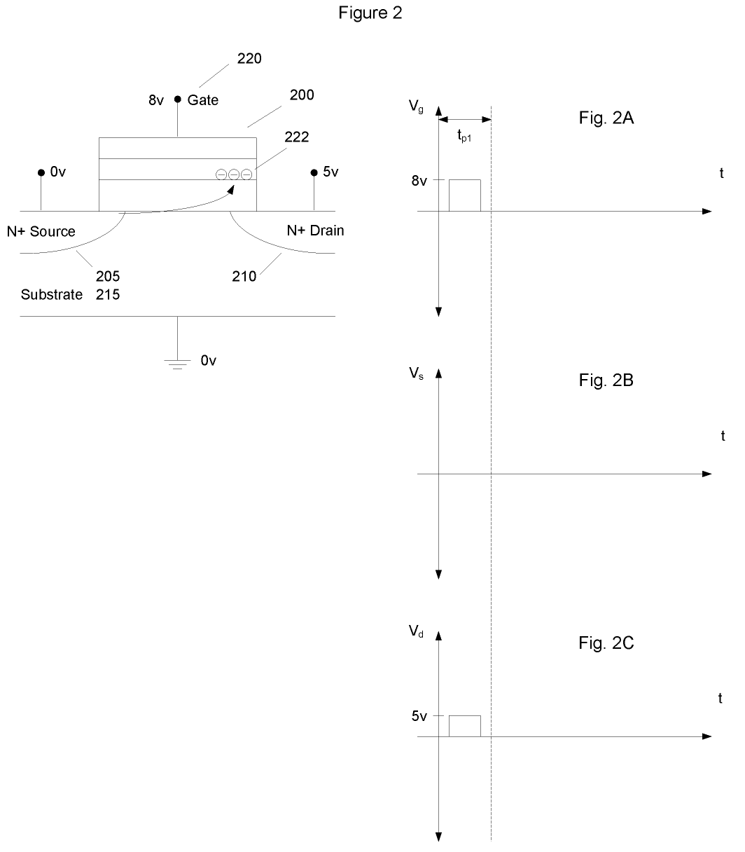

The process by which the drain-side of a dual-bit SONOS memory device 200 is programmed is depicted in FIG. 2. In FIGS. 2-12, similar reference numbers are used to refer to similar features. In FIG. 2, the drain-side of the memory device 200 is programmed by applying a first program pulse comprising a positive bias on the gate 220 and positive bias to the drain region 210. According to one embodiment, the gate and drain biases are about 8 and 5 volts, respectively. The source region 205 is held at about 0 volts potential during this first program pulse operation. Applying the first program pulse establishes an inversion layer in the channel underneath the gate 220 and causes current to move from the drain to the source (i.e., electrons or “majority carriers” moving from the source to the drain). Some of the majority carriers moving from the source 205 to the drain 210 are injected into the nitride region 222 of the gate 220 by hot electron injection. These majority carriers are stored at the drain-side of the nitride region 223 and thereby cause this side of the memory device to be programmed. By trapping a significant amount of charge in the drain-side of nitride region 223, the threshold voltage vₜ of the drain-side of the memory device 200 is effectively raised by several volts. Raising this threshold voltage vₜ effectively places the drain-side of the memory device 200 in a programmed state.

The timing diagrams corresponding to the biases applied to the gate, source, and drain regions during the first programming pulse are depicted in FIGS. 2A, 2B, and 2C, respectively. As shown in these figures, the first program pulse is provided during the time period tₚ₁. FIG. 2A demonstrates that a positive bias 230 is applied to the gate 220 during time period tₚ₁. FIG. 2B demonstrates that no bias is applied to the source 205 at the same time (tₚ₁). FIG. 2C demonstrates that a positive bias 232 is also applied to the drain 210 during time period tₚ₁. According to one embodiment, the first program pulse comprises a 8 volt pulse 230 that is applied to the gate region of the memory device 200 and a 5 volt pulse 232 that is applied to the drain of the memory device 200 during the time period tₚ₁. At the same time tₚ₁ that the first programming pulse is being provided, the source region is maintained at about 0 volts, as shown in FIG. 2B. Other acceptable voltages for the first program pulse include V_{g} in the range of 7-10 v, and V_{d} in the range of 4-6 volts. The first program pulse width can also be in the range of 0.1 μs-1.0 μs.

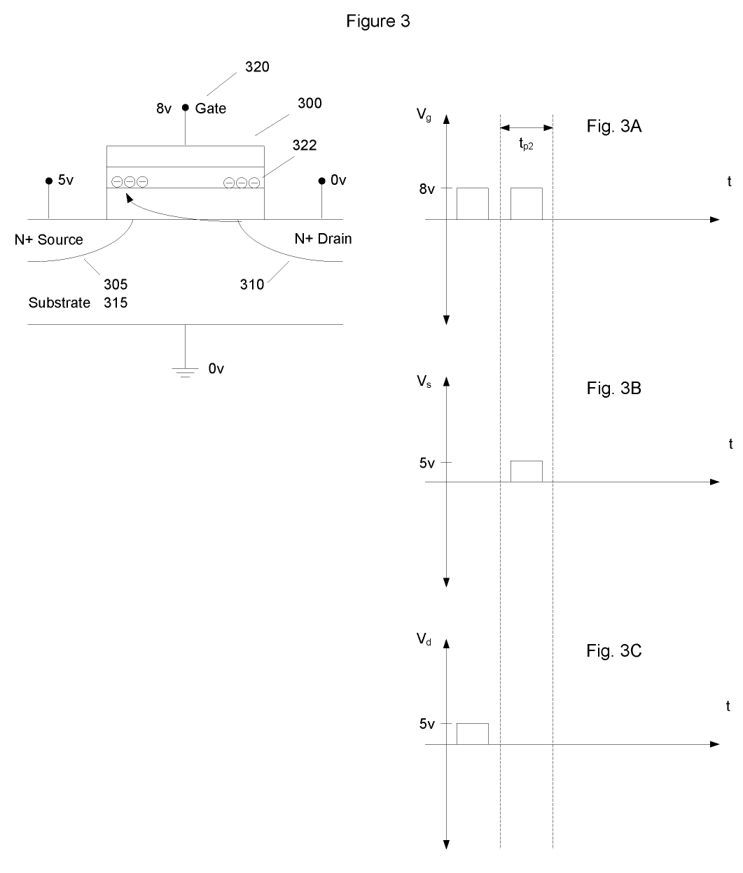

The process by which the source-side of a dual-bit SONOS memory device 300 is programmed is depicted in FIG. 3. In FIG. 3, the source-side of the memory device 300 is programmed by applying a second program pulse comprising a positive bias on the gate 320 and a positive bias to the source region 305. According to one embodiment, the gate and source biases are about 8 and 5 volts, respectively. The drain region 310 is also at about 0 volts during this second program pulse operation. Applying the second program pulse establishes an inversion layer in the channel underneath the gate 320 and causes current to move from the source to the drain (i.e., electrons or “majority carriers” moving from the drain to the source). Some of the majority carriers moving from the drain 310 to the source 305 are injected into the nitride region 322 of the gate 320 by virtue of hot electron injection. These majority carriers are stored at the source-side of the nitride region 324 and thereby cause this side of the memory device to be programmed. By trapping a significant amount of charge in the source-side of nitride region 324, the threshold voltage vₜ of the source-side of the memory device 300 is effectively raised by several volts. Raising this threshold voltage vₜ effectively places the source-side of the memory device 300 in a programmed state.

The timing diagrams corresponding to the biases applied to the gate, source, and drain regions during the second programming pulse are depicted in FIGS. 3A, 3B, and 3C, respectively. As shown in these figures, the second program pulse is provided during the time period tₚ₂. FIG. 3A demonstrates that a positive bias 331 is applied to the gate 320 during time period tₚ₂. FIG. 3B demonstrates that a positive bias 333 is also applied to the source 305 during time period tₚ₂. FIG. 3C demonstrates that the drain 310 is held at 0 v bias during time period tₚ₂. According to one embodiment, the second program pulse comprises a 8 volt pulse 331 that is applied to the gate region of the memory device 300, and a 5 volt pulse 333 that is applied to the source of the memory device 300 during the time period tₚ₂. During this same time period tₚ₂, the voltage bias at the drain region is maintained at 0 volts. Other acceptable voltages for the second program pulse include V_{g} in the range of 7-10 volts, and V_{d} in the range of 4-6 volts. The second program pulse width can also be in the range of 0.1 μs-1.0 μs.

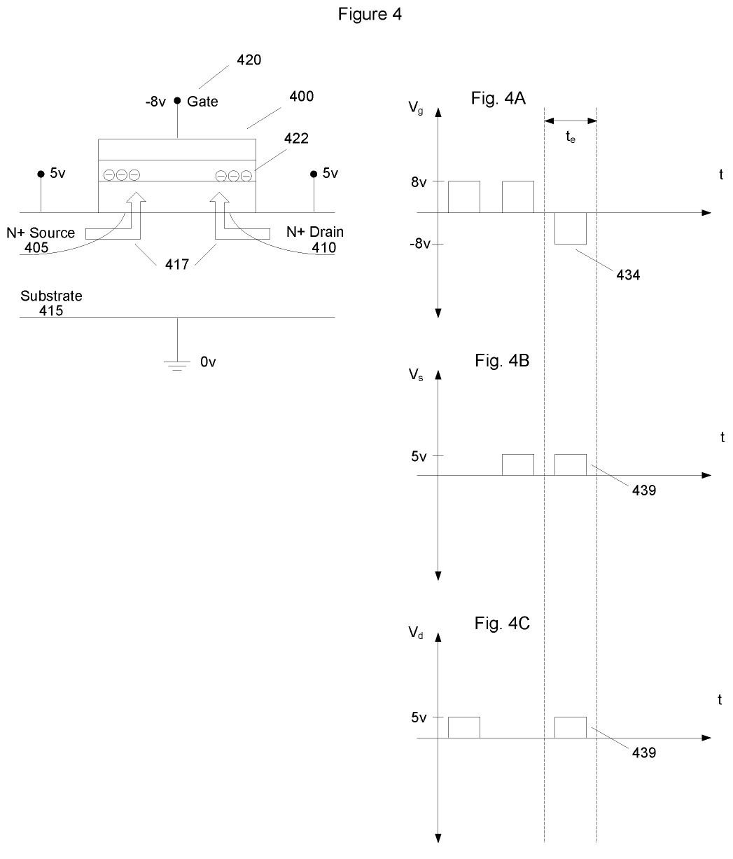

An erase cycle for erasing a dual-bit SONOS memory device 400 in accordance with one embodiment is depicted in FIG. 4. The erase cycle depicted in FIG. 4 can be applied after one or both of the programming steps illustrated in FIGS. 2 and 3, and can be applied immediately thereafter, without an intervening pre-programming step to program any un-programmed bits in the memory device. This reduces the time required to erase the device, thus improving its cycle time. Elimination of a pre-programming step during the erase process for a dual-bit memory device is one beneficial aspect of the improved dual-bias erase. As shown in FIG. 4, the erase pulse comprises a positive bias applied to the source 405 and drain 410 regions. At the same time, a negative bias is applied to the gate region 420. According to one embodiment, the bias applied to the source 405 and drain 410 regions is about 5 volts while the bias applied to the gate region 420 is about −8 volts.

Since a negative bias is applied to the gate region 420, an inversion layer is not formed in the channel under the gate 420, meaning that the memory device is not turned on. At the same time, however, a small amount of leakage current is passed from the source 405 and drain 410 regions into the substrate (represented by the minority carriers 417) because of the positive biases applied thereto. These minority carriers may then be injected into the nitride region 422 of the gate.

As these holes are injected into the nitride region 422, they compensate for the previously-stored negative charges, thus erasing any previous programming in the memory device 400.

The timing diagrams corresponding to the biases applied to the gate, source, and drain regions during the erase pulse are depicted in FIGS. 4A, 4B, and 4C, respectively. As shown in these figures, the erase pulse is provided during the time period tₑ. FIG. 4A demonstrates that a negative bias 434 is applied to the gate 420 during time period tₑ. FIG. 4B demonstrates that a positive bias 436 is also applied to the source 405 during time period tₑ. FIG. 4C demonstrates that a positive bias 437 is also applied to the drain 410 during time period tₑ. According to one embodiment, the erase pulse comprises a bias of about −8 volts 434 that is applied to the gate region of the memory device 400, a bias of about 5 volts 436 that is applied to the source, and a bias of about 5 volts 437 that is applied to the drain during time period tₑ.

In a conventional device, band-to-band hot hole injection (BTBHH) is often used to erase each bit of a SONOS memory device. BTBHH is performed one bit at a time and regions programming step. Thus, for example, the dual-bias erase process described above can be performed faster than the process used in conventional devices because both bits can be erased simultaneously and the pre-programming step can be avoided.

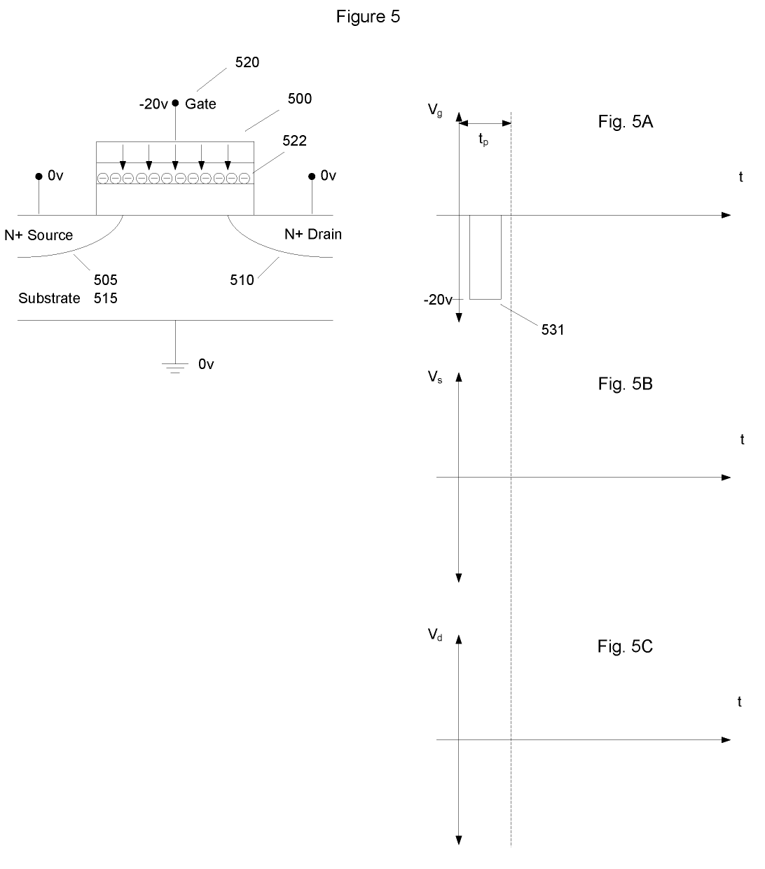

The process by which a single-bit SONOS memory device 500 can be programmed is depicted in FIG. 5. It will be understood, however, that a SONOS device 500 is used by way of example only. In FIG. 5, the device 500 is programmed by applying a program pulse comprising a negative bias on the gate 520 while holding the source 505 and drain 510 regions of the memory device at about 0 volts bias. According to one embodiment, the negative bias applied to the gate is about −20 volts. Other acceptable biases include voltages in the range of −14 to −20 volts. Applying this large negative bias to the gate region 520 injects majority carriers into the nitride region 522 of the gate 520 through Fowler-Nordheim tunneling. Trapping a significant amount of charge in the nitride region 322 effectively raises the threshold voltage vₜ of the device by several volts. Raising this threshold voltage vₜ effectively places the this memory device 500 in a programmed state.

The timing diagrams corresponding to the biases applied to the gate, source, and drain regions during this programming pulse are depicted in FIGS. 5A, 5B, and 5C, respectively. As shown in these figures, the program pulse is provided during the time period tₚ₃. FIG. 5A demonstrates that a negative bias 531 is applied to the gate 520 during time period tₚ₃. FIG. 5B and FIG. 5C demonstrate that the source 405 and drain 410 regions are held to about 0 volts during time period tₚ₃. According to one embodiment, the program pulse comprises a −20 volt pulse 531 that is applied to the gate region of the memory device 500. Other acceptable voltages for the program pulse include V_{g} in the range of −14 to −20 volts, and V_{d} in the range of 4-6 volts. The program pulse width can also be in the range of 1 ms-100 ms.

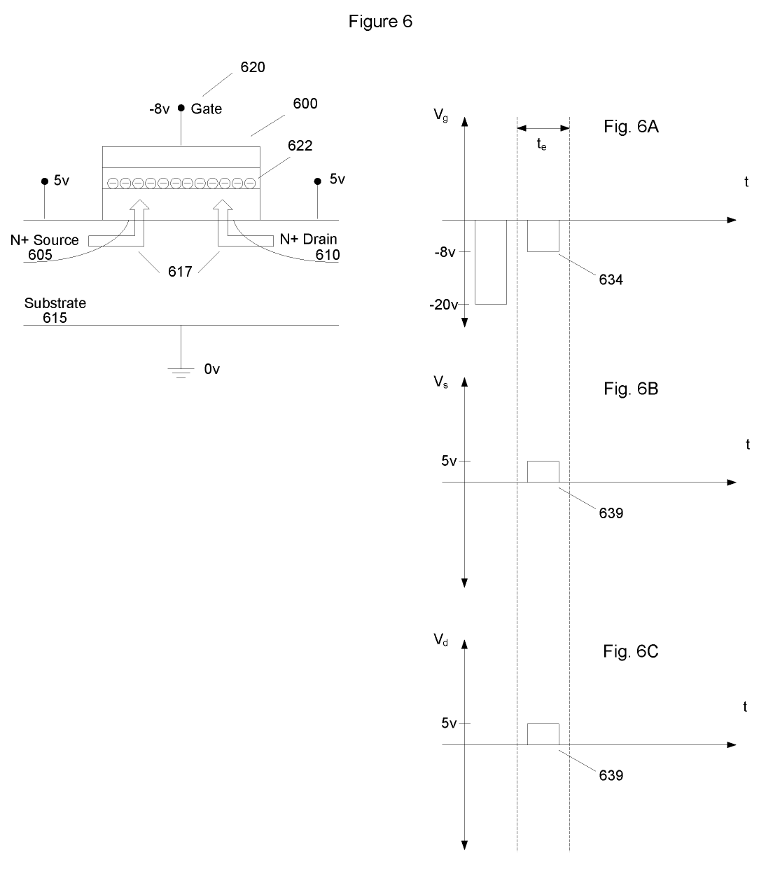

An erase cycle for erasing the single-bit SONOS memory device depicted in FIG. 5 is depicted in FIG. 6. As shown in FIG. 6, the erase pulse comprises a positive bias applied to the source 605 and drain 610 regions of the memory device 600. At the same time, a negative bias is applied to the gate region 620. According to one embodiment, the bias applied to the source 605 and drain 610 regions is about 5 volts and the bias applied to the gate region 620 is about −8 volts. Since a negative bias is applied to the gate region 620, an inversion layer is not formed in the channel under the gate 620, meaning that the memory device 600 is not turned on. At the same time, however, a small amount of leakage current is passed from the source 605 and drain 610 regions into the substrate (represented by the minority carriers 617) because of the positive biases applied thereto. These holes may then be injected into the nitride region 622 of the gate. As these holes are injected into the nitride region 622, they cancel the previously-stored negative charges, thus erasing any previous programming in the memory device 600.

The timing diagrams corresponding to the biases applied to the gate, source, and drain regions during the erase pulse are depicted in FIGS. 6A, 6B, and 6C, respectively. As shown in these figures, the erase pulse is provided during the time period tₑ₂. FIG. 6A demonstrates that a negative bias 634 is applied to the gate 620 during time period tₑ₂. FIG. 6B and FIG. 6C demonstrate that the source 605 and drain 610 regions receive a positive bias 639 during time period tₑ₂. According to one embodiment, the erase pulse comprises a bias 634 of about −8 volts that is applied to the gate region of the memory device 600 and a bias of about 5 volts (639) that is applied to the source and drain regions (605, 610) of the memory device 600 during the time period tₑ₂.

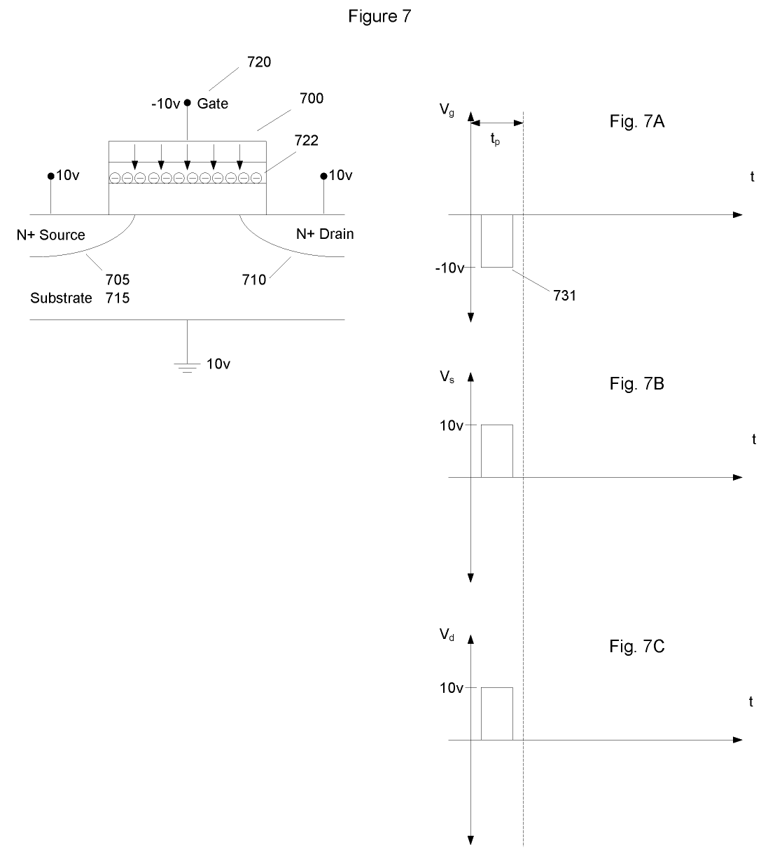

An alternative process by which a single-bit SONOS memory device 700 can be programmed is depicted in FIG. 7. Again, a SONOS device 700 is illustrated by way of example only. In FIG. 7, the memory device 700 is programmed by applying a program pulse comprising a negative bias on the gate 720 and a positive bias on the source 705 and drain 710 regions of the memory device. Here, however, the negative bias applied to gate 720 is less, e.g., about half than that applied in the example of FIG. 5. Accordingly, the process illustrated in FIG. 7 is suitable for low voltage applications.

According to one embodiment, the bias applied to the gate region 720 is about −10 volts while the source 705 and drain 710 regions receive a bias of about 10 volts. Other acceptable voltages for the program pulse include V_{g} in the range of −7 to −10 volts, and V_{d} and Vₛ in the range of 7 to 10 volts. Applying this negative bias to the gate region 520 while also positively biasing the source 705 and drain 710 regions injects majority carriers into the nitride region 722 of the gate 720 through Fowler-Nordheim tunneling. Trapping a significant amount of negative charge in the nitride region 722 effectively raises the threshold voltage vₜ of the memory device 700 by several volts. Raising this threshold voltage vₜ effectively places the memory device 700 in a programmed state.

The timing diagrams corresponding to the biases applied to the gate, source, and drain regions during this programming pulse are depicted in FIGS. 7A, 7B, and 7C, respectively. As shown in these figures, the program pulse is provided during the time period tₚ₄. FIG. 7A demonstrates that a negative bias 731 is applied to the gate 720 during time period tₚ₄. FIG. 7B demonstrates that a positive bias 732 is applied to the source 705 during time period tₚ₄. FIG. 7C demonstrates that a positive bias 733 is applied to the drain 710 during time period tₚ₄. According to one embodiment, the program pulse comprises a negative bias of about −10 volts (731) that is applied to the gate 720 and a positive bias of about 10 volts (732, 733) that are applied to the source and drain (705, 710) during the time period tₚ₄. Other acceptable voltages for the second program pulse include V_{g} in the range of −7 to −10 volts, and V_{d} and Vₛ in the range of 7 to 10 volts. The second program pulse width can also be in the range of 1 ms-100 ms.

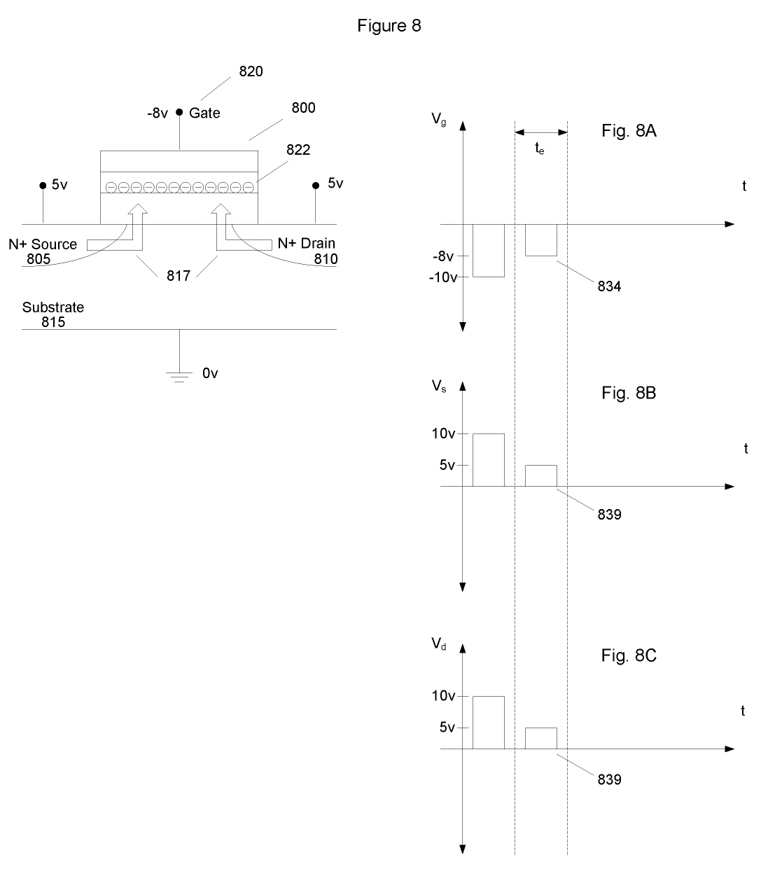

An erase cycle for erasing the single-bit SONOS memory device depicted in FIG. 7 is depicted in FIG. 8. As shown in FIG. 8, the erase pulse comprises a positive bias applied to the source 805 and drain 810 regions of the memory device 800. At the same time, a negative bias is applied to the gate region 820. According to one embodiment, the bias applied to the source 805 and drain 810 regions is about 5 volts while the bias applied to the gate region 820 is about −8 volts. Since a negative bias is applied to the gate region 820, an inversion layer is not formed in the channel under the gate 820, meaning that the memory device 800 is not turned on. At the same time, however, a small amount of leakage current is passed from the source 805 and drain 810 regions into the substrate (represented by the minority carriers 817) because of the positive biases applied thereto. These minority carriers may then be injected into the nitride region 822 of the gate. As these minority carriers are injected into the nitride region 822, they cancel the previously-stored negative charges, thus erasing any previous programming in the memory device 800.

The timing diagrams corresponding to the biases applied to the gate, source, and drain regions during the erase pulse are depicted in FIGS. 8A, 8B, and 8C, respectively. As shown in these figures, the erase pulse is provided during the time period tₑ₃. FIG. 8A demonstrates that a negative bias 834 is applied to the gate 820 during time period tₑ₃. FIG. 8B and FIG. 8C demonstrate that a positive bias 836 and 837 is applied to the source 805 and drain 810 regions respectively, during time period tₑ₃. According to one embodiment, the erase pulse comprises a bias of about −8 volts 834 that is applied to the gate region of the memory device 800 and a bias (836, 837) of about 5 volts that is applied to the source and drain regions (805, 810) of the memory device 800 during the time period tₑ₃.

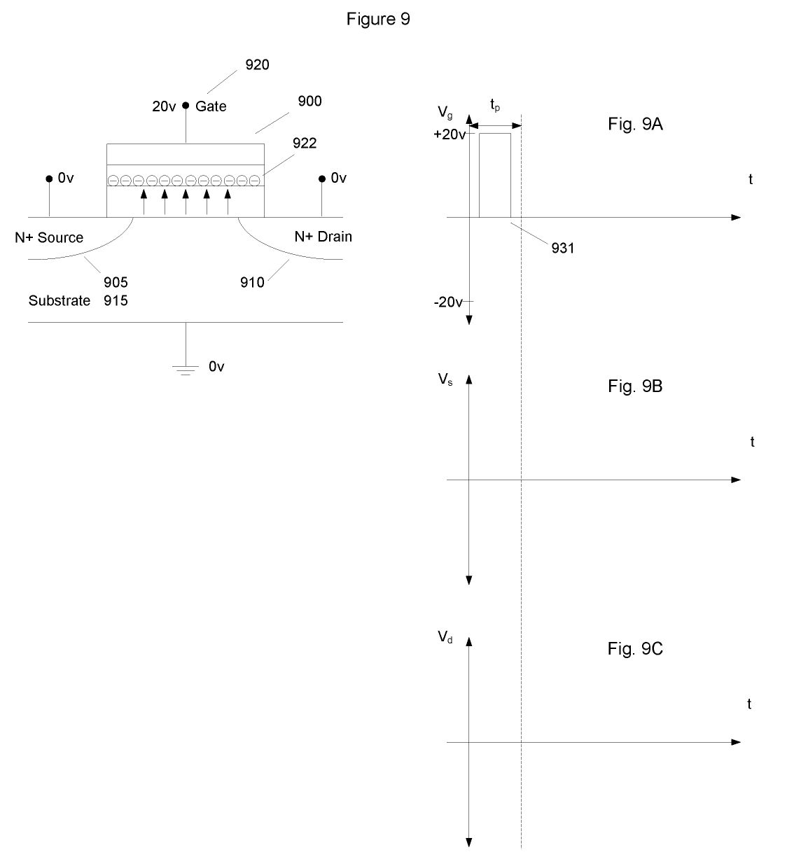

An alternative process by which a single-bit SONOS memory device 900 can be programmed is depicted in FIG. 9. Again, a SONOS device is shown by way of example only. In FIG. 9, the memory device 900 is programmed by applying a program pulse comprising a positive bias on the gate 920 while the source 905 and drain 910 regions of the memory device at about 0 volts. According to one embodiment, the positive bias applied to the gate region 920 is about 20 volts while the source 905 and drain 910 regions are held at about 0 volts. Other acceptable biases for the gate region include the range of 14 volts to 20 volts. Applying this large positive bias to the gate region 920 while holding the source 905 and drain 910 regions at about 0 v injects majority carriers into the nitride region 922 of the gate 920 from the substrate 915 through Fowler-Nordheim tunneling. Trapping a significant amount of negative charge in the nitride region 922 effectively raises the threshold voltage vₜ of the memory device 900 by several volts. Raising this threshold voltage vₜ effectively places the this memory device 900 in a programmed state.

The timing diagrams corresponding to the biases applied to the gate, source, and drain regions during this programming pulse are depicted in FIGS. 9A, 9B, and 9C, respectively. As shown in these figures, the program pulse is provided during the time period tₚ₅. FIG. 9A demonstrates that a positive bias 931 is applied to the gate 920 during time period tₚ₅. FIG. 9B and FIG. 9C demonstrate that a the source 705 and drain 710 regions are held at about 0 volts during time period tₚ₅. According to one embodiment, the program pulse comprises a positive bias 931 of about 20 volts that is applied to the gate region 920 of the memory device 900 while the source 905 and drain 910 regions are held at about 0 volts bias during time period tₚ₅. Other acceptable voltages for the program pulse include V_{g} in the range of 14 volts to 20 volts. The program pulse width can also be in the range of 1 ms-100 ms.

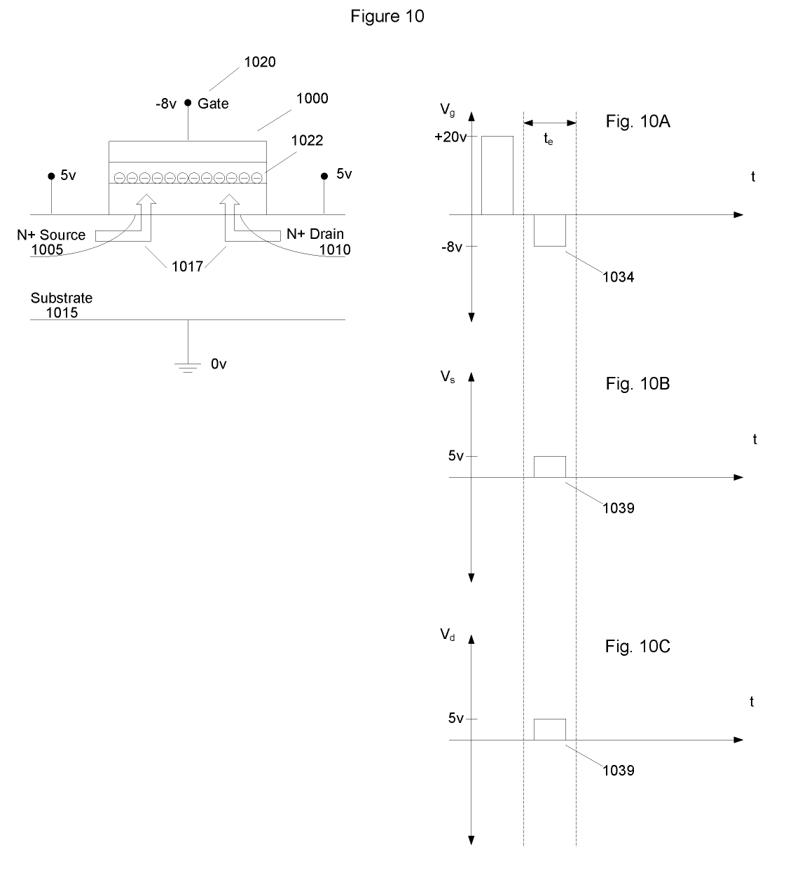

An erase cycle for erasing the single-bit SONOS memory device depicted in FIG. 9 is depicted in FIG. 10. As shown in FIG. 10, the erase pulse comprises a positive bias applied to the source 1005 and drain 1010 regions of the memory device 1000. At the same time, a negative bias is applied to the gate region 1020. According to one embodiment, the bias applied to the source 1005 and drain 1010 regions is about 5 volts while the bias applied to the gate region 1020 is about −8 volts. Since a negative bias is applied to the gate region 1020, an inversion layer is not formed in the channel under the gate 1020, meaning that the memory device 1000 is not turned on. At the same time, however, a small amount of leakage current is passed from the source 1005 and drain 1010 regions (represented by the minority carriers 1017) to the substrate region 1015 because of the positive biases applied thereto. These holes may then be injected into the nitride region 1022 of the gate 1020. As these holes are injected into the nitride region 1022, they cancel the previously-stored negative charges, thus erasing any previous programming in the memory device 1000.

The timing diagrams corresponding to the biases applied to the gate, source, and drain regions during the erase pulse are depicted in FIGS. 10A, 10B, and 10C, respectively. As shown in these figures, the erase pulse is provided during the time period tₑ₄. FIG. 10A demonstrates that a negative bias 1034 is applied to the gate 1020 during time period tₑ₄. FIG. 10B and FIG. 10C demonstrate that a positive bias 1036 and 1037 is applied to the source 1005 and drain 1010 regions respectively, during time period tₑ₄. According to one embodiment, the erase pulse comprises a negative bias 1034 of about −8 volts that is applied to the gate 1020 and a bias 1036 and 1037 of about 5 volts that is applied to the source and drain regions (1005, 1010) of the memory device 800 during the time period tₑ₄.

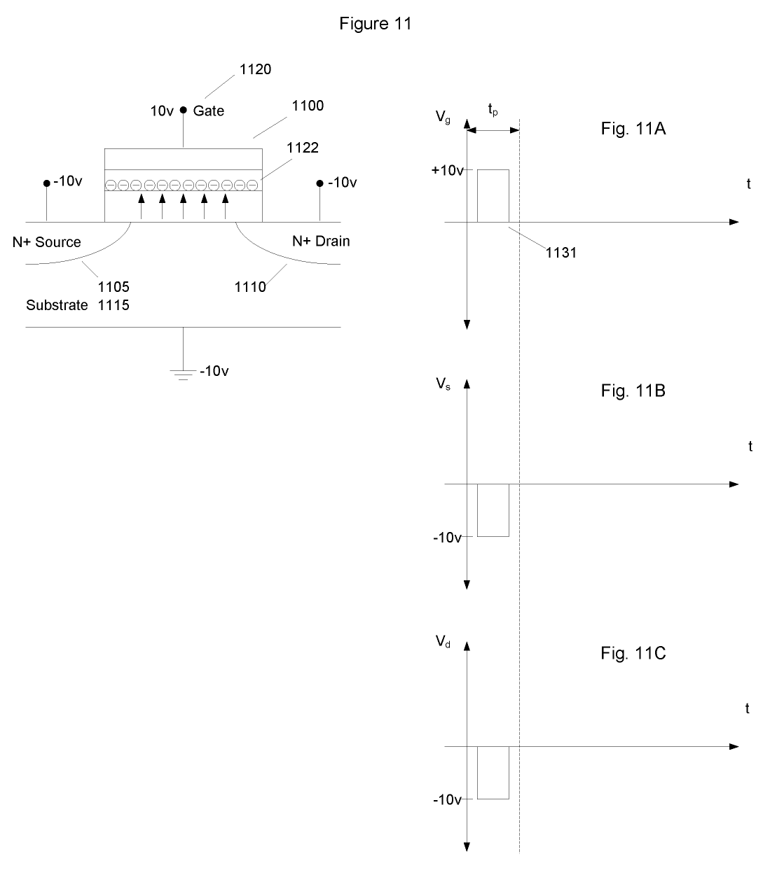

An alternative process by which a single-bit SONOS memory device 1100 can be programmed is depicted in FIG. 11. Again, a SONOS device is shown by way of example only. In FIG. 11, the memory device 1100 is programmed by applying a program pulse comprising a positive bias on the gate 1120 while applying a negative bias to the source 1105 and drain 1110 regions of the memory device 1100. Here, however, the bias applied to gate region 1120 is less than that applied in the example of FIG. 9. Accordingly, the process illustrated in FIG. 11 is suitable for low voltage applications.

According to one embodiment, the bias applied to the gate region 1120 is about 10 volts while the bias applied to the source 1105 and drain 1110 regions is about −10 volts. Other acceptable voltages for the program pulse include V_{g} in the range of 7-10 v, and V_{d}, Vₛ, and V_{sub} in the range of −7 to −10 volts. Applying this positive bias to the gate region 1020 while applying a negative bias to the source 1105 and drain 1110 regions injects electrons into the nitride region 1122 of the gate 1120 from the substrate 1115 through Fowler-Nordheim tunneling. Trapping a significant amount of negative charge in the nitride region 1122 effectively raises the threshold voltage vₜ of the memory device 1100 by several volts. Raising this threshold voltage vₜ effectively places the this memory device 1100 in a programmed state.

The timing diagrams corresponding to the biases applied to the gate, source, and drain regions during this programming pulse are depicted in FIGS. 11A, 11B, and 11C, respectively. As shown in these figures, the program pulse is provided during the time period tₚ₆. FIG. 11A demonstrates that a positive bias 1131 is applied to the gate 1120 during time period tₚ₆. FIG. 11B and FIG. 11C demonstrate that a negative bias 1132 and 1133 is applied to the source 1105 and drain 1110 regions respectively, during time period tₚ₆. According to one embodiment, the program pulse comprises a positive bias 1131 of about 10 volts that is applied to the gate 1120 and a negative bias 1132 and 1136 of about −10 volts applied to the source 1105 and drain 1110 regions respectively, of the memory device 1100 during the time period tₚ₆. Other acceptable voltages for the program pulse include V_{g} in the range of 7 to 10 volts, and V_{d}, Vₛ, and V_{sub} in the range of −7 to −10 volts. The program pulse width can also be in the range of 1 ms-100 ms.

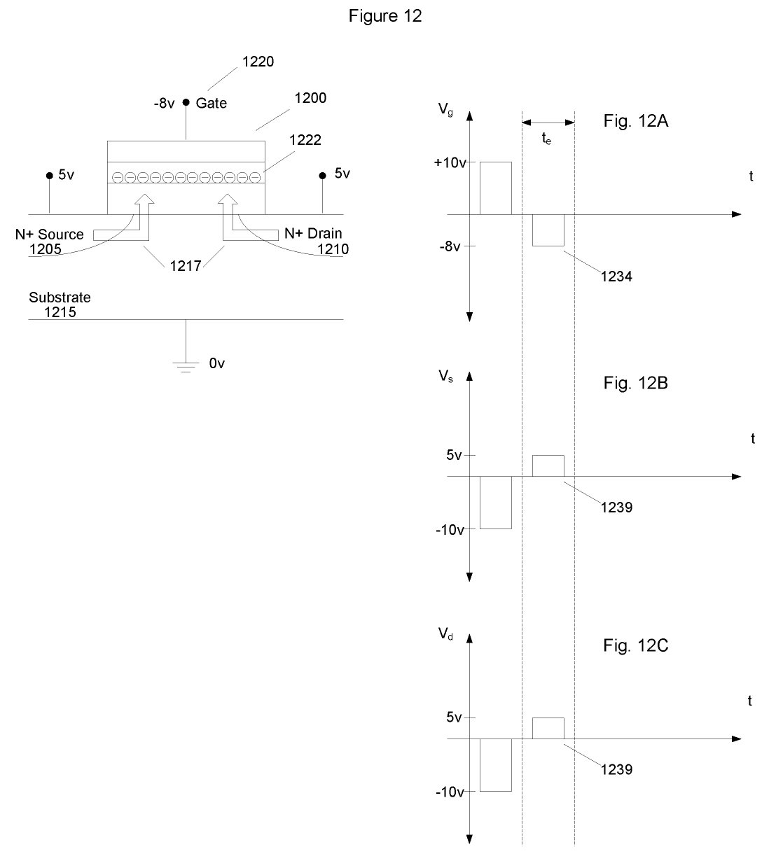

An erase cycle for erasing the single-bit SONOS memory device depicted in FIG. 11 is depicted in FIG. 12. As shown in FIG. 12, the erase pulse comprises a positive bias applied to the source 1205 and drain 1210 regions of the memory device 1200. At the same time, a negative bias is applied to the gate region 1220. According to one embodiment, the bias applied to the source 1205 and drain 1210 regions is about 5 volts while the bias applied to the gate region 1220 is about −8 volts. Since a negative bias is applied to the gate region 1220, an inversion layer is not formed in the channel under the gate 1220, meaning that the memory device 1200 is not turned on. At the same time, however, a small amount of leakage current is passed from the source 1205 and drain 1210 regions (represented by the minority carriers 1217) because of the positive biases applied thereto. These holes may then be injected into the nitride region 1222 of the gate. As these minority carriers are injected into the nitride region 1222, they cancel the previously-stored negative charges, thus erasing any previous programming in the memory device 1200.

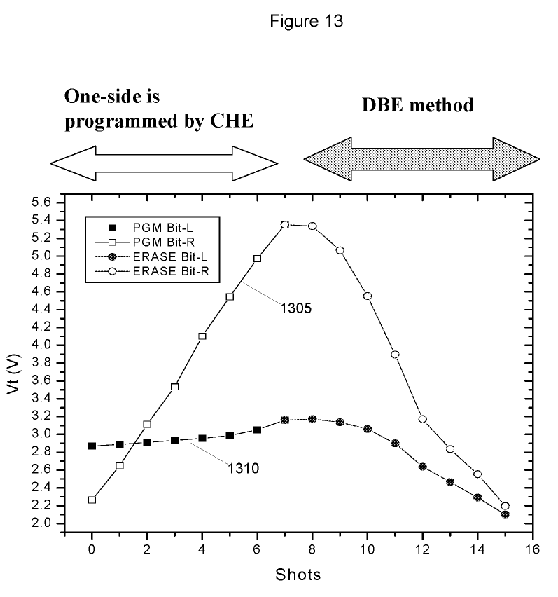

The timing diagrams corresponding to the biases applied to the gate, source, and drain regions during the erase pulse are depicted in FIGS. 12A, 12B, and 13C, respectively. As shown in these figures, the erase pulse is provided during the time period tₑ₅. FIG. 12A demonstrates that a negative bias 1234 is applied to the gate 1220 during time period tₑ₅. FIG. 12B and FIG. 12C demonstrate that a positive bias 1236 and 1237 is applied to the source 1205 and drain 1210 regions respectively, during time period tₑ₅. According to one embodiment, the erase pulse comprises a negative bias of about 8 volts (1234) that is applied to the gate 1220 and a bias of about 5 volts (1236, 1237) that is applied to the source and drain regions (1205, 1210) of the memory device 1200 during the time period tₑ₅.

The program and erase curves for a two-bit SONOS memory device are depicted in FIG. 13. In FIG. 13, curve 1305 depicts the effect of the program and erase functions on the right-hand bit of the memory device. Initially, as the right-hand bit is programmed, curve 1305 demonstrates that the threshold voltage vₜ of the right-hand side of the memory device is raised from about 2.3 volts to about 5.4 volts. Curve 1310 depicts the effects of this programming operation on the left-hand bit of the memory device. During the same time that the right-hand bit is being programmed, curve 1310 is raised only from about 2.9 volts to about 3.2 volts. This demonstrates that the program pulse for a right-hand bit of a SONOS memory device, has as a small, but manageable effect on the left-hand bit of the SONOS memory device.

During the dual-bias erase (DBE) cycle, an erase pulse, such as the one described in FIG. 4, is applied to the memory device. Since the electric field adjacent to the programmed right-hand bit will much greater than the electric fields adjacent to the un-programmed left-hand bit, more of the dislodged holes will be attracted to the right-hand side of the memory device than the left-hand side. As a result, the erase curve corresponding to the right-hand bit 1310 descends more steeply than the curve corresponding to the left-hand bit 1310. Eventually, curve 1305 and 1310 arrive at the same approximate threshold voltage (about 2.2 volts) at nearly the same time. This effectively negates the over-erase program seen in many memory devices.

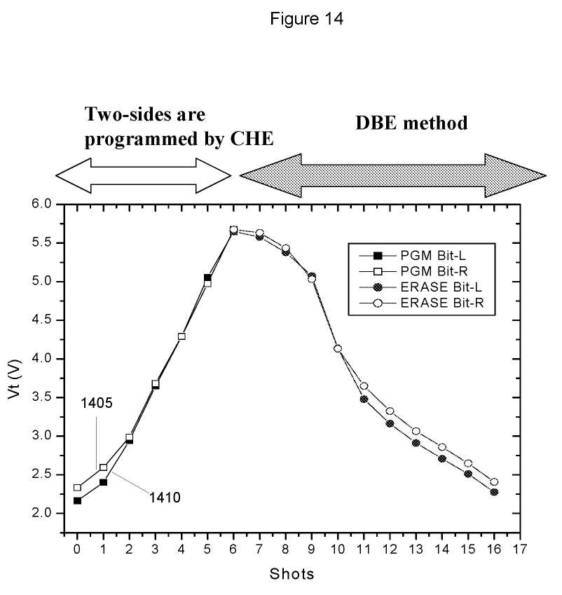

Another aspect of the program and erase curves for a two-bit SONOS memory device is depicted in FIG. 14. In FIG. 14, curve 1405 depicts the effect of the program and erase functions on the right-hand bit of the memory device while curve 1410 depicts the effects of these operations on the left-hand bit of the memory device. In FIG. 14, both the right-hand and left-hand bits are being programmed at the same time. During this programming time (1415), the threshold voltage vₜ for both bits is raised from about 2.3 volts to about 5.7 volts. During the dual-bias erase cycle 1420, such as the erase pulse described in FIG. 4, appropriate erase pulses are applied to the memory device, thereby reducing the threshold voltage vₜ of each side of the memory device.

While certain embodiments of the inventions have been described above, it will be understood that the embodiments described are by way of example only. Accordingly, the inventions should not be limited based on the described embodiments. Rather, the scope of the inventions described herein should only be limited in light of the claims that follow when taken in conjunction with the above description and accompanying drawings.

What is claimed is:

1. A method for erasing a non-volatile memory device comprising a source region formed in a substrate, a drain region formed in the substrate, a gate region formed on the substrate and overlapping the source and drain regions, and a storage layer within the gate region, the method comprising:
providing a positive bias to the source and drain regions at the same time to generate minority carriers; and
providing a negative bias to the gate region to attract the minority carriers into the storage layer.

2. A method according to claim 1, wherein the gate region comprises an oxide-nitride-oxide structure.

3. A method according to claim 1, wherein the positive bias comprises a bias of about 5 volts measured from the source and drain regions to the substrate and wherein the negative bias comprises a bias of about −8 volts measured from the gate region to the substrate.

4. A method according to claim 2, wherein the positive and negative biases are provided for a period of about 100 microseconds.

5. A method according to claim 1, wherein the memory device comprises a dual-bit SONOS memory cell.

6. A method according to claim 5, wherein the erase step does not include a pre-programming operation.

7. A method according to claim 1, wherein the memory device is part of a NAND memory circuit.

8. A method according to claim 1, wherein the memory device is part of a NOR memory circuit.

9. A method for erasing a dual-bit SONOS memory device comprising a source region formed in a substrate, a drain region formed in the substrate, and a gate region formed on the substrate and overlapping the source and drain regions, the gate region comprising an oxide-nitride-oxide layer, the method comprising:
providing a positive bias to the source and drain regions so as to generate minority carriers; and
providing a negative bias to the gate region so as to attract the minority carriers into the nitride region of the gate.

10. A method according to claim 9, wherein only one side of the dual-bit memory device is programmed prior to the erase step.

11. A method according to claim 10, wherein no pre-programming step is provided prior to the erase step.
